(19) United States
(12) Patent Application Publication
(10) Pub. No.: US 2024/0339411 A1
(43) Pub. Date: Oct. 10, 2024

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: CHENGTAR WU, Suwon-si (KR); JONGKOOK KIM, Suwon-si (KR); SEUNGYEON RHEE, Suwon-si (KR); CHOONGBIN YIM, Suwon-si (KR)

(21) Appl. No.: 18/395,839

(22) Filed: Dec. 26, 2023

(30) Foreign Application Priority Data
Apr. 7, 2023 (KR) 10-2023-0046375

(51) Int. Cl. H01L 23/538; H01L 21/48; H01L 23/00; H01L 25/00; H01L 25/18; H10B 80/00

(52) U.S. Cl. CPC H01L 23/5385; H01L 21/486; H01L 24/13; H01L 24/16; H01L 24/32; H01L 24/73; H01L 25/18; H01L 25/50; H10B 80/00; H01L 24/05; H01L 24/08; H01L 2224/05647; H01L 2224/08225; H01L 2224/13111; H01L 2224/13116; H01L 2224/13139; H01L 2224/13147; H01L 2224/13155; H01L 2224/16227; H01L 2224/32225; H01L 2224/73204

(57) ABSTRACT

A semiconductor package includes a substrate, a first three-dimensional integrated circuit structure on the substrate, and a second three-dimensional integrated circuit structure on the substrate, where the first three-dimensional integrated circuit structure may include a first interposer including a first semiconductor die, and a second semiconductor die on the first interposer, where the second three-dimensional integrated circuit structure may include a second interposer including a third semiconductor die, and a fourth semiconductor die on the second interposer, where the substrate may include an electrical routing configured to relay a signal from the second semiconductor die and a signal from the fourth semiconductor die.

### CROSS-REFERENCE TO RELATED APPLICATION

This application claims priority to and the benefit under 35 U.S.C. § 119 of Korean Patent Application No. 10-2023-0046375 filed in the Korean Intellectual Property Office on Apr. 7, 2023, the entire contents of which is incorporated herein by reference.

### BACKGROUND

### (a) Field of the Invention

The present disclosure relates to a semiconductor package and a method for manufacturing the same.

### (b) Description of the Related Art

A semiconductor chip can be electrically coupled to a semiconductor substrate and transmit and receive signals with other semiconductor chips. However, since semiconductor substrates may have relatively large circuit line widths compared to the processed semiconductor chips, an intermediary that can mitigate the difference in line width between the processed semiconductor chips and the semiconductor substrates may be used to connect the processed semiconductor chips and semiconductor substrates.

A silicon bridge may be embedded in the semiconductor substrate, and semiconductor chips can be mounted on the semiconductor substrate having the silicon bridge, such that a connection structure is formed between the silicon bridge and the semiconductor chips.

The silicon bridge can be attached to the semiconductor substrate using a die attached film (DAF) or an adhesive, and the DAF or adhesive may have fluidity in a subsequent heat treatment process. Thus, the silicone bridge may be moved due to the fluidity of the DAF or adhesive. Also, in the process of embedding the silicon bridge in the semiconductor substrate, the silicon bridge may be incorrectly attached to the semiconductor substrate. As such, if the silicon bridge is moved or the silicon bridge is incorrectly attached during the manufacturing process, there is a risk of decreasing the yield of the semiconductor package. Furthermore, as the integration density of passive or active devices within a given area of a semiconductor package increases, more silicon bridges are required.

By having a silicon bridge embedded in a semiconductor substrate, where the silicon bridge can be silicon and the semiconductor substrate can be an organic material with a higher coefficient of thermal expansion than silicon, warpage can result.

### SUMMARY

The present disclosure attempts to provide a semiconductor package without using a silicon bridge, to address a problem where the silicon bridge is moved or the silicon bridge is incorrectly attached during the manufacturing process, and the problem of warpage of the semiconductor package due to the silicon bridges, three-dimensional integrated circuit structures including an interposer including a lower semiconductor die and an upper semiconductor die on the interposer are formed, the interposer electrically connects a fine pitch I/O of high-performance semiconductor chips within the upper semiconductor die and a normal pitch I/O of a semiconductor substrate on which the three-dimensional integrated circuit (3D IC) structure is mounted, and the semiconductor substrate may include electrical routing that relays signals between the upper semiconductor dies of the three-dimensional integrated circuit (3D IC) structures.

In various embodiments, a semiconductor package includes a first three-dimensional integrated circuit structure on a substrate, and a second three-dimensional integrated circuit structure on the substrate, where the first three-dimensional integrated circuit structure may include a first interposer including a first semiconductor die, and a second semiconductor die on the first interposer, where the second three-dimensional integrated circuit structure may include a second interposer including a third semiconductor die, and a fourth semiconductor die on the second interposer, where the substrate may include an electrical routing configured to relay a signal from the second semiconductor die and a signal from the fourth semiconductor die.

In various embodiments, the first interposer may electrically connect the substrate with the second semiconductor die, and the second interposer may electrically connect the substrate and the fourth semiconductor die.

In various embodiments, the substrate may include an Ajinomoto build-up film (ABF) substrate.

In various embodiments, the first semiconductor die and the third semiconductor die may include a silicon interposer, respectively.

In various embodiments, the silicon interposer may include a plurality of through-silicon vias (TSV).

In various embodiments, the first interposer and the second interposer may further include a redistribution layer structure, respectively.

In various embodiments, the second semiconductor die may include system-on-chip (SOC).

In various embodiments, the fourth semiconductor die may include a high bandwidth memory (HBM).

In various embodiments, the first three-dimensional integrated circuit structure may further include a first molding material that molds the second semiconductor die on the first semiconductor die, and the second three-dimensional integrated circuit structure may further include a second molding material that molds the fourth semiconductor die on the third semiconductor die.

In various embodiments, a semiconductor package includes a plurality of first connection members electrically connecting a first three-dimensional integrated circuit structure to a substrate, and a plurality of second connection members electrically connecting a second three-dimensional integrated circuit structure to the substrate, where the first three-dimensional integrated circuit structure may include a first interposer including a first semiconductor die, a second semiconductor die on the first interposer, and a plurality of third connection members electrically connecting the second semiconductor die to the first interposer, where the second three-dimensional integrated circuit structure may include a second interposer including a third semiconductor die, a fourth semiconductor die on the second interposer, and a plurality of fourth connection members electrically connecting the fourth semiconductor die to the second interposer, and where the substrate may include an electrical routing configured to relay a signal from the second semiconductor die and a signal from the fourth semiconductor die.

In various embodiments, a pitch of neighboring first connection members among the plurality of first connection members may is larger than a pitch of neighboring third connection members among the plurality of third connection members. A pitch of neighboring second connection members among the plurality of second connection members may is larger than a pitch of neighboring fourth connection members among the plurality of fourth connection members.

In various embodiments, the plurality of first connection members and the plurality of second connection members may include solder balls or conductive bumps.

In various embodiments, the plurality of third connection members and the plurality of fourth connection members may include micro-bumps.

In various embodiments, a semiconductor package may further include a first insulation member disposed between the substrate and the first three-dimensional integrated circuit structure, and configured to surround the plurality of first connection members, and a second insulation member disposed between the substrate and the second three-dimensional integrated circuit structure, and configured to surround the plurality of second connection members.

In various embodiments, the first insulation member and the second insulation member may include a molded under-fill (MUF).

In various embodiments, the first three-dimensional integrated circuit structure may further include a third insulation member, where the third insulation member is disposed between the first interposer and the second semiconductor die and surrounds the plurality of third connection members. The second three-dimensional integrated circuit structure may further include a fourth insulation member, where the fourth insulation member is disposed between the second interposer and the fourth semiconductor die and surrounds the plurality of fourth connection members.

The third insulation member and the fourth insulation member may include a nonconductive film (NCF).

A method for manufacturing a semiconductor package includes forming a through-silicon via in each of a first wafer and a second wafer, forming a first redistribution layer structure on the first wafer to form a first interposer, and forming a second redistribution layer structure on the second wafer to form a second interposer, mounting a first semiconductor die on the first interposer to form a first three-dimensional integrated circuit structure, and mounting a second semiconductor die on the second interposer to form a second three-dimensional integrated circuit structure, and mounting the first three-dimensional integrated circuit structure and the second three-dimensional integrated circuit structure on a substrate where the substrate may include an electrical routing configured to relay a first signal from the first semiconductor die and a second signal from the second semiconductor die.

A method for manufacturing a semiconductor package may further include pretreating the substrate, prior to the mounting the first three-dimensional integrated circuit structure and the second three-dimensional integrated circuit structure on the substrate.

A method for manufacturing a semiconductor package may further include filling an under-fill material between the substrate and the first three-dimensional integrated circuit structure, and between the substrate and the second three-dimensional integrated circuit structure.

Three-dimensional integrated circuit structures including an interposer including a lower semiconductor die and an upper semiconductor die on the interposer may be formed, the interposer may electrically connect a fine pitch I/O of high-performance semiconductor chips within the upper semiconductor die and a normal pitch I/O of a semiconductor substrate on which the three-dimensional integrated circuit (3D IC) structure is mounted, and the semiconductor substrate may include electrical routing that relays signals between the upper semiconductor dies of the three-dimensional integrated circuit (3D IC) structures.

Accordingly, because signals may be relayed between upper semiconductor dies having I/O of a fine pitch without using the silicon bridge, the problem that silicon bridge is moved or the silicon bridge is incorrectly attached during the manufacturing process, and the problem of warpage of the semiconductor package due to the silicon bridges are solved, and thus, yield of the semiconductor package may be enhanced.

In addition, in contrast to the case of using a silicon bridge where the structure of the semiconductor package is complicated to adjust the overlay error of the silicon bridges that may be caused because the silicon bridge is moved or the silicon bridge is incorrectly attached during the manufacturing process, according to the present disclosure, the silicon bridge is not used, and accordingly, the semiconductor package may be formed in a simpler structure.

### BRIEF DESCRIPTION OF THE DRAWINGS

FIG. 1 is a cross-sectional view of a three-dimensional integrated circuit (3D IC) structure with an interposer and semiconductor dies, according to an embodiment of the disclosure.

FIG. 2 is a cross-sectional view of a three-dimensional integrated circuit (3D IC) structure with the interposer, including a first semiconductor die, and a second semiconductor die on the interposer, according to an embodiment of the disclosure.

FIG. 3 to FIG. 9 and FIG. 11 to FIG. 13 are cross-sectional view showing manufacturing a three-dimensional integrated circuit (3D IC) structure starting with through-silicon vias (TSV) in a first semiconductor die, according to an embodiment of the disclosure.

FIG. 4 is a cross-sectional view showing a redistribution layer structure formed on the first semiconductor die, according to an embodiment of the disclosure.

FIG. 5 is a cross-sectional view showing an external connection structure formed on a redistribution layer structure, according to an embodiment of the disclosure.

FIG. 6 is a cross-sectional view showing a carrier bonded under an external connection structure, according to an embodiment of the disclosure.

FIG. 7 is a cross-sectional view showing a first semiconductor die formed by grinding a back side of a wafer, according to an embodiment of the disclosure.

FIG. 8 is a cross-sectional view showing a second semiconductor die mounted on the first semiconductor die, according to an embodiment of the disclosure.

FIG. 9 is a cross-sectional view showing an insulation member formed between the first and second semiconductor dies, according to an embodiment of the disclosure.

FIG. 10 is a cross-sectional view showing the second semiconductor die on the first semiconductor die by a hybrid bonding, according to an embodiment of the disclosure.

FIG. 11 is a cross-sectional view showing a molding material on the second and first semiconductor die, according to an embodiment of the disclosure.

FIG. 12 is a cross-sectional view showing planarizing a molding material, according to an embodiment of the disclosure.

FIG. 13 is a cross-sectional view showing de-bonding a carrier from an external connection structure, according to an embodiment of the disclosure.

FIG. 14 is a cross-sectional view showing a semiconductor package in which a first three-dimensional integrated circuit (3D IC) structure and a second three-dimensional integrated circuit (3D IC) structure are mounted on a substrate, according to an embodiment of the disclosure.

FIG. 15 is a cross-sectional view showing a substrate, according to an embodiment of the disclosure.

FIG. 16 is a cross-sectional view showing mounting a first three-dimensional integrated circuit (3D IC) structure and a second three-dimensional integrated circuit (3D IC) structure on a substrate, according to an embodiment of the disclosure.

FIG. 17 is a cross-sectional view showing forming a first insulation member, according to an embodiment of the disclosure.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package and a manufacturing method of a semiconductor package according to an embodiment is describe with reference to the drawings.

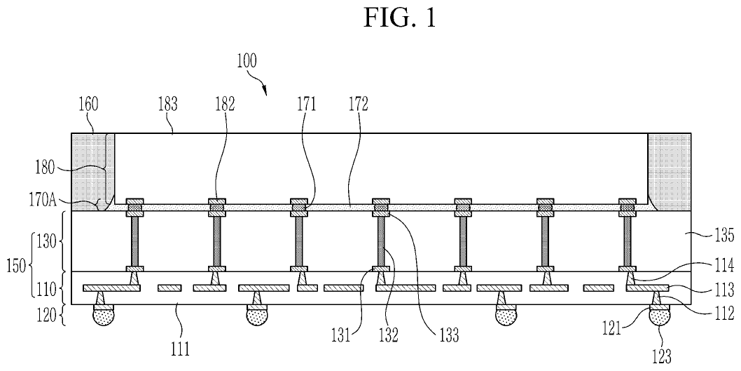

FIG. 1 is a cross-sectional view of a three-dimensional integrated circuit (3D IC) structure 100 in which an interposer 150, including a redistribution layer structure 110 and a first semiconductor die 130, and a second semiconductor die 180 on the interposer 150 are electrically and physically connected by a connection member 171.

Referring to FIG. 1, the three-dimensional integrated circuit (3D IC) structure 100 may include the interposer 150, including a redistribution layer (RDL) structure 110 and the first semiconductor die 130, the second semiconductor die 180, a molding material 160, an interconnection structure 170A, and an external connection structure 120.

In various embodiments, the interposer 150 may include the redistribution layer structure 110, which may be a redistribution layer interposer. The interposer 150 may include the first semiconductor die 130, where the first semiconductor die 130 may be a silicon interposer. The second semiconductor die 180 may include a high-performance semiconductor, which requires a high routing density and is implemented to have a fine line width. Due to a pitch difference between the fine pitch I/O of the high-performance semiconductor and the normal pitch I/O of the conventional substrate, the fine pitch I/O of the high-performance semiconductor may not be electrically connected to the normal pitch I/O of the conventional substrate. Accordingly, if the lower semiconductor die of the 3D IC structure is implemented as an interposer including a redistribution layer structure and a silicon interposer, the high-performance semiconductor and the substrate may be electrically connected by the interposer.

The redistribution layer structure 110 may include a dielectric layer 111, and first redistribution vias 112, first redistribution lines 113, and second redistribution vias 114 in the dielectric layer 111. A redistribution layer structure including a larger or smaller number of redistribution lines and redistribution vias is also included in the scope of the present disclosure.

The dielectric layer 111 may protect and electrically insulate the first redistribution vias 112, the first redistribution lines 113 and the second redistribution vias 114. The first semiconductor die 130 may be disposed on an upper surface of the dielectric layer 111, and the external connection structure 120 may be disposed on a lower surface of the dielectric layer 111, where the lower surface of the dielectric layer 111 can form a bottom surface of the redistribution layer structure 110.

In various embodiments, the first redistribution via 112 may be disposed between the first redistribution line 113 and a conductive pad 121 of the external connection structure 120, where the conductive pad 121 can be on the lower surface of the dielectric layer 111. The first redistribution via 112 may electrically connect the first redistribution line 113 and the conductive pad 121 in a vertical direction, where the first redistribution line 113 may be embedded in the thickness of the dielectric layer 111. The first redistribution line 113 may be disposed between the first redistribution via 112 and the second redistribution via 114. The first redistribution line 113 may electrically connect the first redistribution via 112 and the second redistribution via 114 in a horizontal direction. The second redistribution via 114 may be disposed between the first redistribution line 113 and a lower connection pad 131, where the lower connection pad 131 can be on an upper surface of the dielectric layer 111. The first semiconductor die 130 can be on and electrically connected to the redistribution layer structure 110. The second redistribution via 114 may electrically connect the first redistribution line 113 and the lower connection pad 131 of the first semiconductor die 130 in the vertical direction, where the second redistribution via 114 may be directly connected to the lower connection pad 131 of the first semiconductor die 130 without any other connection member. In an embodiment, a width of an uppermost portion of the first redistribution via 112 and the second redistribution via 114 may be smaller than a width of a lowermost portion, where the first redistribution via 112 and the second redistribution via 114 may have tapered cross-sectional shapes. In an embodiment, a horizontal pitch between the first redistribution vias 112 of the redistribution layer structure 110 may be larger than a pitch of the second redistribution via 114 of the redistribution layer structure 110, where the lower connection pads 131 can be configured to be aligned with electrical connections of the first semiconductor die 130.

The first semiconductor die 130 may be a silicon interposer. When the first semiconductor die 130 is a silicon interposer, a hybrid bonding process may be performed to stack the second semiconductor die 180 on the first semiconductor die 130. In various embodiments, the first semiconductor die 130 may include through-silicon vias (TSV) 132, lower connection pads 131, and upper connection pads 133. In an embodiment, the first semiconductor die 130 may not include an active device and/or a passive device.

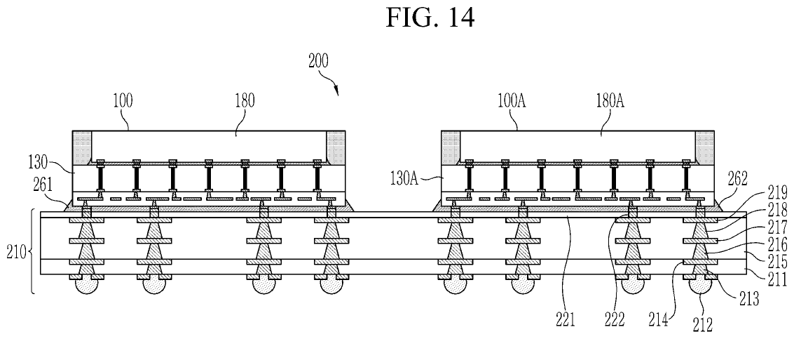

A through-silicon via (TSV) 132 may be disposed within a wafer (die base) 135, where the through-silicon via (TSV) 132 may be between the lower connection pad 131 and the upper connection pad 133, where the through-silicon via (TSV) 132 may electrically connect the lower connection pad 131 and the upper connection pad 133. In the three-dimensional integrated circuit (3D IC) structure 100, because the second semiconductor die 180 may be spaced apart from a substrate 210 (see FIG. 14) carrying signals and power, the speed at which the second semiconductor die 180 receives signals and power and responds thereto may be increased by disposing the through-silicon via (TSV) 132 in the first semiconductor die 130 and electrically connecting it to the second semiconductor die 180.

The lower connection pad 131 may be disposed between the through-silicon via (TSV) 132 and the second redistribution via 114, where the lower connection pad 131 may electrically connect the through-silicon via (TSV) 132 and the second redistribution via 114. The upper connection pad 133 may be disposed between the through-silicon via (TSV) 132 and the connection member 171, where the upper connection pad 133 may electrically connect the through-silicon via (TSV) 132 and the connection member 171.

In various embodiments, the second semiconductor die 180 may include a semiconductor chip 183. The second semiconductor die 180 may also include a connection member 182. In an embodiment, the semiconductor chip 183 may be a semiconductor chip including a high-performance circuit. In an embodiment, the semiconductor chip 183 may include a system-on-chip (SOC). In an embodiment, the semiconductor chip 183 may include a memory structure, DRAM, or high bandwidth memory (HBM). In an embodiment, the semiconductor chip 183 may include at least one of a central processing unit (CPU), a graphic processing unit (GPU), a memory, a controller, a codec, a sensor, and a communication unit.

In various embodiments, a molding material 160 may be formed on the first semiconductor die 130 and the second semiconductor die 180. The molding material 160 may be molded around the second semiconductor die 180 and on the first semiconductor die 130. In an embodiment, the molding material 160 may be an epoxy molding compound (EMC). In another embodiment, the molding material 160 may be formed of a thermosetting resin such as epoxy resin.

The interconnection structure 170A may be disposed between the first semiconductor die 130 and the second semiconductor die 180. The interconnection structure 170A may include connection members 171 and an insulation member 172, where the insulation member 172 can be around the connection members 171. The connection member 171 may electrically connect the upper connection pad 133 of the first semiconductor die 130 and a connection member 182 of the second semiconductor die 180. In an embodiment, the connection member 171 may include a micro-bump. The insulating member 172 can surround and protect the connection member 171 between the first semiconductor die 130 and the second semiconductor die 180. In an embodiment, the insulation member 172 may include a non-conductive film (NCF).

In various embodiments, a pitch of neighboring first connection members 123 among a plurality of first connection members 123 may be larger than a pitch of neighboring third connection members 171 among a plurality of third connection members 171. A pitch of neighboring second connection members 123 among a plurality of second connection members 123 may be larger than a pitch of neighboring fourth connection members 171 among a plurality of fourth connection members 171.

In various embodiments, the external connection structure 120 may be disposed on a bottom surface of the redistribution layer structure 110. The external connection structure 120 may include conductive pads 121 and external connection members 123. The conductive pad 121 may electrically connect the first redistribution via 112 of the redistribution layer structure 110 the external connection member 123. The external connection member 123 may electrically connect the three-dimensional integrated circuit (3D IC) structure 100 to external device. In an embodiment, a pitch between the external connection members 123 may be larger than a pitch between the connection members 171. In an embodiment, the external connection member 123 may include a solder ball or a conductive bump. A plurality of first connection members 123 and a plurality of second connection members 123 may be solder balls or conductive bumps.

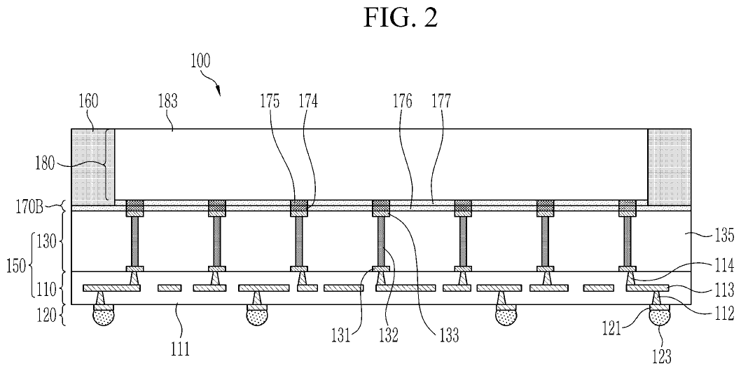

FIG. 2 is a cross-sectional view of the three-dimensional integrated circuit (3D IC) structure 100 in which the interposer 150 may be electrically and physically connected by hybrid bonding to a second semiconductor die 180 on the interposer 150.

Referring to FIG. 2, the three-dimensional integrated circuit (3D IC) structure 100 may include the interposer 150 including the redistribution layer structure 110 and the first semiconductor die 130, the second semiconductor die 180, the molding material 160, an interconnection structure 170B, and the external connection structure 120.

In various embodiments, the first semiconductor die 130 and the second semiconductor die 180 of the three-dimensional integrated circuit (3D IC) structure 100 may be bonded by hybrid bonding. Hybrid bonding can bond two devices by fusing the same materials of the two devices using the bonding properties of the same material. Here, the term hybrid means that two different types of bonding are made, for example, two devices are bonded by a first type of metal-metal bonding and a second type of non-metal-non-metal bonding. Hybrid bonding makes it possible to form I/Os with a fine pitch.

In various embodiments, the interconnection structure 170B may include first bonding pads 174 and a first silicon insulation layer 176 on an upper surface of the first semiconductor die 130, second bonding pads 175 and a second silicon insulation layer 177 on a bottom surface of the second semiconductor die 180. The first bonding pad 174 may be directly bonded to the second bonding pad 175 by metal-metal hybrid bonding, and the first silicon insulation layer 176 may be directly bonded to the second silicon insulation layer 177 by non-metal-non-metal hybrid bonding. The first bonding pad 174 may be formed on or otherwise directly bonded to the upper connection pads 133 of the first semiconductor die 130. The molding material 160 may be on the first silicon insulation layer 176, where the first silicon insulation layer 176 can separate the molding material 160 from the wafer 135.

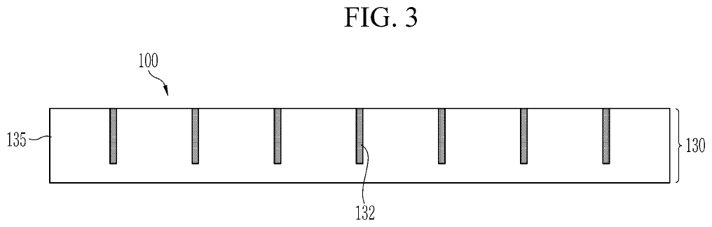

FIG. 3 to FIG. 9 and FIG. 11 to FIG. 13 are cross-sectional views showing steps of a method for manufacturing the three-dimensional integrated circuit (3D IC) structure 100 of FIG. 1.

FIG. 3 is a cross-sectional view showing a first semiconductor die 130, where through-silicon vias (TSV) 132 may be formed into a wafer 135. In various embodiments, the through silicon via (TSV) 132 may be formed by forming holes penetrating an insulating material of the wafer 135 and filling the holes with a conductive material. In an embodiment, the hole of the through silicon via (TSV) 132 may be formed by deep etching. In another embodiment, the hole of the through silicon via (TSV) 132 may be formed by a laser. In an embodiment, the hole of the through silicon via (TSV) 132 may be filled with a conductive material by electrolytic plating. In an embodiment, the through-silicon via (TSV) 132 may be made of a conductive material, including, but not limited to, tungsten, aluminum, copper, and combinations thereof.

In various embodiments, a barrier layer may be formed between the through silicon vias (TSVs) 132 and the insulating material of the wafer 135. In an embodiment, barrier layer may include at least one of titanium, tantalum, titanium nitride, tantalum nitride, or an alloy thereof.

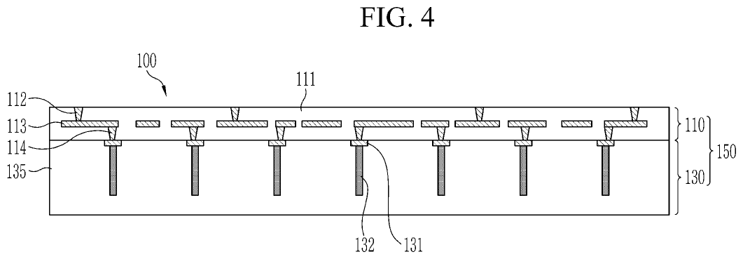

FIG. 4 is a cross-sectional view showing that the redistribution layer structure 110 can be formed on the first semiconductor die 130.

Referring to FIG. 4, the redistribution layer structure 110 may be formed on a front side of the first semiconductor die 130.

Lower connection pads 131 may be formed in the wafer 135, where the lower connection pads 131 can be electrically connected to the through silicon vias (TSVs) 132. A lower connection pad 131 may be formed on and electrically connected to each of a plurality of the through silicon vias (TSVs) 132. In an embodiment, the lower connection pads 131 may be formed by depositing a silicon layer and then performing photolithography, development, etching, and electrolytic plating. In an embodiment, the lower connection pad 131 may include a conductive material, including, but not limited to, copper, aluminum, silver, tin, gold, nickel, lead, titanium, and combinations thereof.

In various embodiments, a dielectric layer 111 can be formed on the lower connection pad 131 and the silicon layer including the lower connection pads 131 or on the first semiconductor die 130. Since the dielectric layer 111 may be directly formed on the lower connection pad 131 and the silicon layer, or on the first semiconductor die 130, connection members such as micro-bumps and solder bumps are not used. In an embodiment, the dielectric layer 111 may include a photoactive polymer layer. The photoactive polymer is a material capable of forming fine patterns by applying a photolithography process. In an embodiment, the dielectric layer 111 may include a photoimageable dielectric (PID) used in a redistribution layer process. In an embodiment, the photoimageable dielectric (PID) may include a polyimide-based photoactive polymer, a novolac-based photoactive polymer, polybenzoxazole, a silicon-based polymer, an acrylate-based polymer, or an epoxy-based polymer. In another embodiment, dielectric layer 111 is formed of polymers such as PBO and polyimide. In another embodiment, the dielectric layer 111 is formed of an inorganic dielectric material such as a silicon nitride, a silicon oxide, and the like. In an embodiment, the dielectric layer 111 may be formed by a CVD, ALD, or PECVD process.

After the dielectric layer 111 is formed, via holes are formed by selectively etching the dielectric layer 111, and the second redistribution vias 114 can be formed by filling a conducting material into the via holes. A width of an uppermost portion of each second redistribution via among the second redistribution vias 114 may be larger than a width of a lowermost portion, where the second redistribution vias 114 can be tapered. In a subsequent process, because the first semiconductor die 130 on which the redistribution layer structure 110 is formed is turned over to manufacture a final product, for each second redistribution via among the second redistribution vias 114 of the final product, a width of an uppermost portion may be smaller than a width of a lowermost portion.

In various embodiments, a dielectric layer 111 is further deposited on the second redistribution vias 114 and the initial thickness of dielectric layer 111, openings can be formed by selectively etching the additionally deposit dielectric layer 111 to form openings, and the first redistribution lines 113 may be formed by filling a conducting material into the openings.

In various embodiments, the dielectric layer 111 is additionally deposited on the first redistribution lines 113 and the existing dielectric layer 111, via holes are formed by selectively etching the additionally deposited dielectric layer 111, and the first redistribution vias 112 is formed by filling a conducting material into the via holes. For the same reason as the second redistribution vias 114, in the final product, the width of the uppermost portion of each first redistribution via among the first redistribution vias 112 is smaller than the width of the lowermost portion.

In an embodiment, the first redistribution vias 112, the first redistribution lines 113 and the second redistribution vias 114 may include at least one of copper, aluminum, tungsten, nickel, gold, tin, titanium, or an alloy thereof. In an embodiment, the first redistribution vias 112, the first redistribution lines 113 and the second redistribution vias 114 may be formed by performing sputtering process. In another embodiment, the first redistribution vias 112, the first redistribution lines 113 and the second redistribution vias 114 may be formed by performing an electrolytic plating process after forming a seed metal layer.

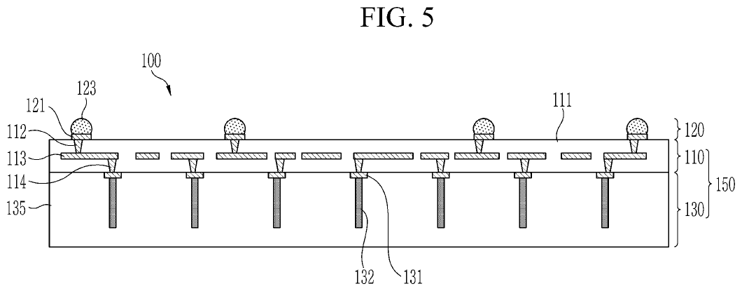

FIG. 5 is a cross-sectional view showing that the external connection structure 120 is formed on the redistribution layer structure 110.

Referring to FIG. 5, the external connection structure 120 can be formed on the redistribution layer structure 110. The conductive pads 121 are formed on the dielectric layer 111 of the redistribution layer structure 110, and the external connection members 123 are formed on the conductive pads 121. In an embodiment, the conductive pad 121 may include at least one of copper, nickel, zinc, gold, silver, platinum, palladium, chromium, titanium, or an alloy thereof. In an embodiment, the conductive pad 121 may be formed by performing a sputtering process or by performing an electrolytic plating process after forming a seed metal layer. In an embodiment, the external connection member 123 may include at least one of tin, silver, lead, nickel, copper, or an alloy thereof.

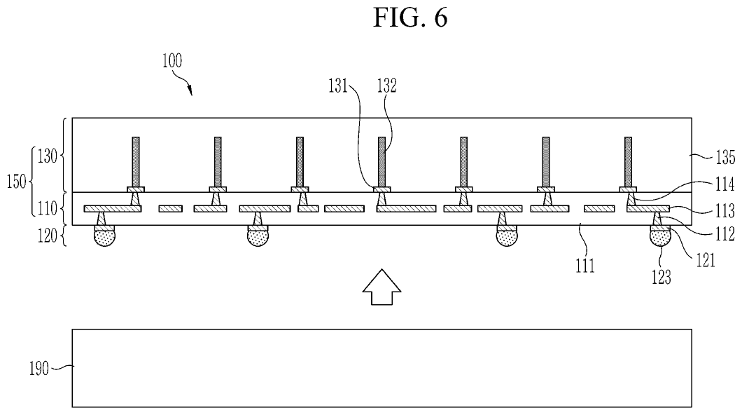

FIG. 6 is a cross-sectional view showing that a carrier 190 can be bonded under the external connection structure 120, as a step in a method for manufacturing a three-dimensional integrated circuit (3D IC) structure 100.

Referring to FIG. 6, the interposer 150 including the redistribution layer structure 110 and the first semiconductor die 130 on which the external connection structure 120 is formed is reversed (e.g., flipped over) and aligned, and a carrier 190 is bonded to the external connection structure 120. The carrier 190 may include, for example, a silicon-based material such as glass or a silicon oxide, an organic material, or another material such as an aluminum oxide, a combination of these materials, and the like.

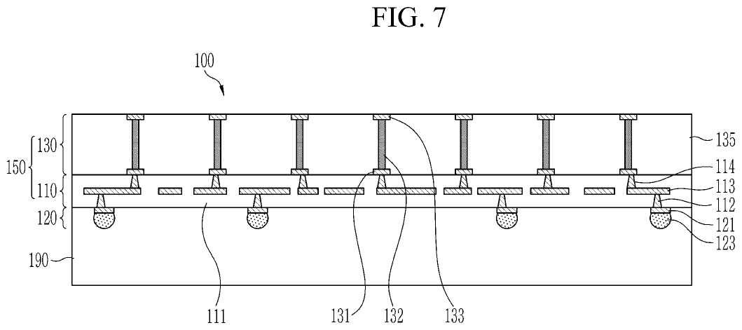

FIG. 7 is a cross-sectional view showing that the first semiconductor die 130 is formed by grinding a back side of a wafer.

Referring to FIG. 7, the back side of the wafer 135 can be removed by grinding, and the upper connection pads 133 of the first semiconductor die 130 are formed.

In various embodiments, the upper connection pad 133 may be formed on the through silicon via (TSV) 132, where the upper connection pad 133 can be electrically connected to the TSV 132. In an embodiment, the upper connection pad 133 may be formed on the back side of the wafer 135 by performing photo-development, etching, and electrolytic plating. In an embodiment, the upper connection pad 133 may include at least one of copper, aluminum, silver, tin, gold, nickel, lead, titanium, and an alloy thereof.

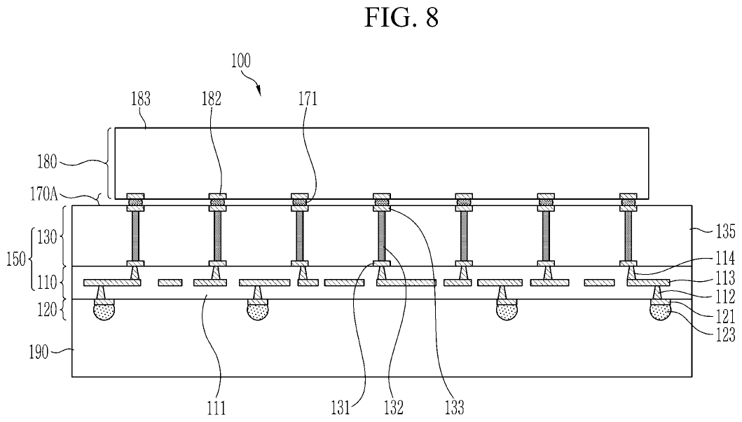

FIG. 8 is a cross-sectional view showing that the second semiconductor die 180 can be mounted on the first semiconductor die 130, where the second semiconductor die 180 can be mounted by flip-chip bonding.

Referring to FIG. 8, a second semiconductor die 180 can be mounted on the first semiconductor die 130 using a connection member 171. The upper connection pad 133 of the first semiconductor die 130 and the connection member 182 of the second semiconductor die 180 can be electrically connected using the connection member 171, where the connection member 171 can be interposed between the connection member 182 and the upper connection pad 133. The connection member 171 may be formed on the upper connection pad 133 or the connection member 182. In an embodiment, the connection member 171 may include a micro-bump. In an embodiment, the connection member 171 may include at least one of tin, silver, lead, nickel, copper or an alloy thereof.

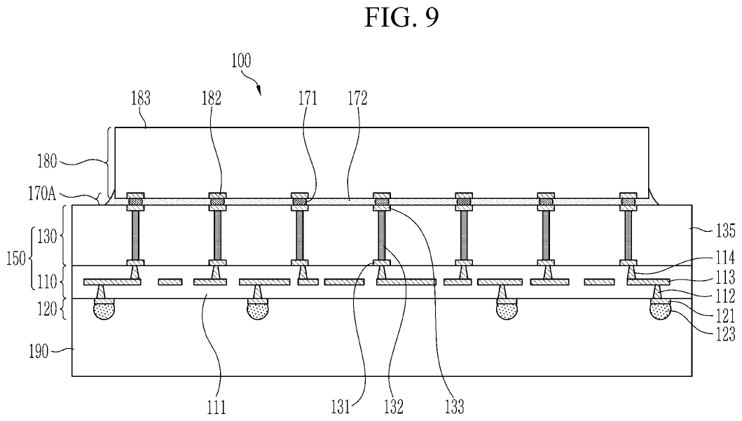

FIG. 9 is a cross-sectional view showing forming the insulation member 172 between the first semiconductor die 130 and the second semiconductor die 180.

Referring to FIG. 9, the insulating member 172 is disposed between the first semiconductor die 130 and the second semiconductor die 180 to surround the connecting members 171. In this way, stress between the first semiconductor die 130 and the second semiconductor die 180 may be alleviated by forming the insulation member 172 between the first semiconductor die 130 and the second semiconductor die 180. In an embodiment, the insulation member 172 may include a molded under-fill (MUF).

In another embodiment, prior to mounting the second semiconductor die 180 on the first semiconductor die 130, a non-conductive film (NCF) may be attached to the first semiconductor die 130 or the second semiconductor die 180 to act as the insulation member 172. The non-conductive film (NCF) can have an adhesiveness for attachment to the first semiconductor die 130 or the second semiconductor die 180. The non-conductive film (NCF) can have an uncured state capable of being deformed by an external force. The non-conductive film (NCF) may be attached by heating at a temperature of about 170° C. to about 300° C. for about 1 second to about 20 seconds. Then, the second semiconductor die 180 may be stacked on the non-conductive film (NCF). The connection member 171 provided on the second semiconductor die 180 can penetrate the non-conductive film (NCF) and contact the upper connection pad 133 of the first semiconductor die 130.

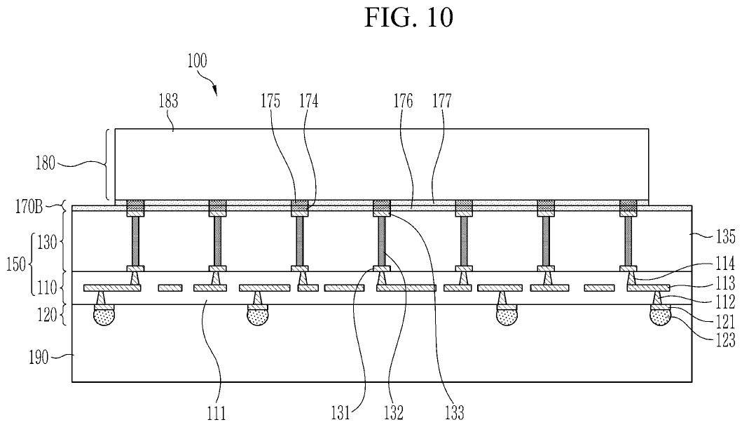

FIG. 10 is a cross-sectional view showing mounting the second semiconductor die 180 on the first semiconductor die 130 by a hybrid bonding. FIG. 10 is a cross-sectional view showing steps of a method for manufacturing the three-dimensional integrated circuit (3D IC) structure 100 of FIG. 2.

Referring to FIG. 10, the first semiconductor die 130 and the second semiconductor die 180 can be bonded to each other by performing hybrid bonding. The first bonding pad 174 on the upper surface of the first semiconductor die 130 and the second bonding pad 175 of the bottom surface of the second semiconductor die 180 may be directly bonded by metal-metal hybrid bonding. By the metal-metal hybrid bonding, metal bonding is made at an interface between the first bonding pad 174 on the upper surface of the first semiconductor die 130 and the second bonding pad 175 of the bottom surface of the second semiconductor die 180. In an embodiment, the first bonding pad 174 and the second bonding pad 175 may include copper. In another embodiment, the first bonding pad 174 and the second bonding pad 175 may be a metallic material to which the hybrid bonding may be applicable.

In various embodiments, the first bonding pad 174 on the upper surface of the first semiconductor die 130 and the second bonding pad 175 of the bottom surface of the second semiconductor die 180 may be made of the same material, such that after the hybrid bonding, the interface between the first bonding pad 174 on the upper surface of the first semiconductor die 130 and the second bonding pad 175 of the bottom surface of the second semiconductor die 180 may disappear. The first semiconductor die 130 and the second semiconductor die 180 may be electrically connected through the first bonding pad 174 on the upper surface of the first semiconductor die 130 and the second bonding pad 175 on the bottom surface of the second semiconductor die 180.

In various embodiments, a first silicon insulation layer 176 may be formed on an upper surface of the first semiconductor die 130, and a second silicon insulation layer 177 may be formed on the bottom surface of the second semiconductor die 180. The first silicon insulation layer 176 on the upper surface of the first semiconductor die 130 and the second silicon insulation layer 177 of the bottom surface of the second semiconductor die 180 may be directly bonded by non-metal-non-metal hybrid bonding. By the non-metal-non-metal hybrid bonding, a covalent bond is made at an interface between the first silicon insulation layer 176 on the upper surface of the first semiconductor die 130 and the second silicon insulation layer 177 of the bottom surface of the second semiconductor die 180.

In an embodiment, the first silicon insulation layer 176 and the second silicon insulation layer 177 may include silicon oxide or TEOS formation oxide. In an embodiment, the first silicon insulation layer 176 and the second silicon insulation layer 177 may include SiO₂. In another embodiment, the first silicon insulation layer 176 and the second silicon insulation layer 177 may be silicon nitride, silicon oxynitride, or other suitable dielectric material. In another embodiment, the first silicon insulation layer 176 and the second silicon insulation layer 177 may include SiN or SiCN.

The first silicon insulation layer 176 on the upper surface of the first semiconductor die 130 and the second silicon insulation layer 177 of the bottom surface of the second semiconductor die 180 may be made of the same material, such that, after the hybrid bonding, the interface between the first silicon insulation layer 176 on the upper surface of the first semiconductor die 130 and the second silicon insulation layer 177 of the bottom surface of the second semiconductor die 180 may disappear.

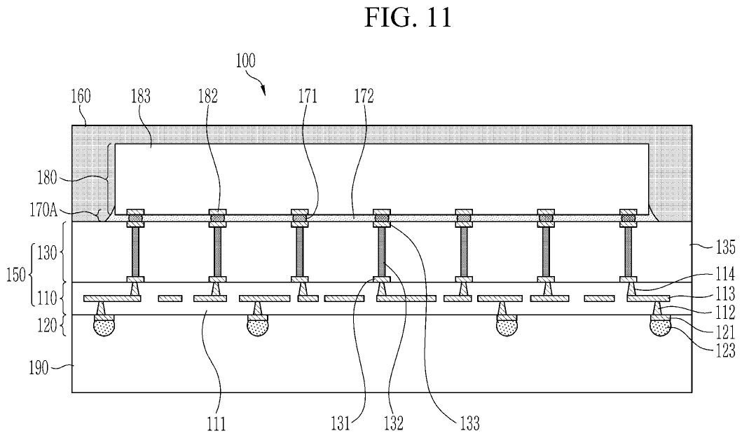

FIG. 11 is a cross-sectional view showing a molding material on the second semiconductor die 180 and the first semiconductor die 130.

Referring to FIG. 11, a molding material 160 may be applied to the second semiconductor die 180 and the first semiconductor die 130. In some embodiments, a process of molding with the molding material 160 may include a compression molding or transfer molding process. The molding material 160 may cover an upper surface of the second semiconductor die 180 and extend along the sidewalls of the second semiconductor die 180 to an exposed surface of the wafer 135 around a periphery of the second semiconductor die 180. The molding material 160 may be in direct contact with a portion of the wafer 135.

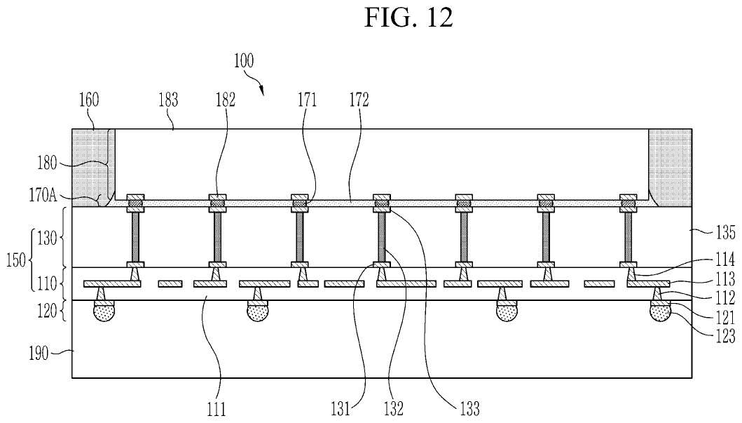

FIG. 12 is a cross-sectional view showing planarizing the molding material 160, as a step in a method for manufacturing the three-dimensional integrated circuit (3D IC) structure 100.

Referring to FIG. 12, chemical mechanical polishing (CMP) may be performed to remove and level the upper surface of the molding material 160. The upper surface of the molding material 160 may be planarized by applying a CMP process, where the CMP process can remove a sufficient amount of molding material 160 to expose an upper surface of the semiconductor chip 183.

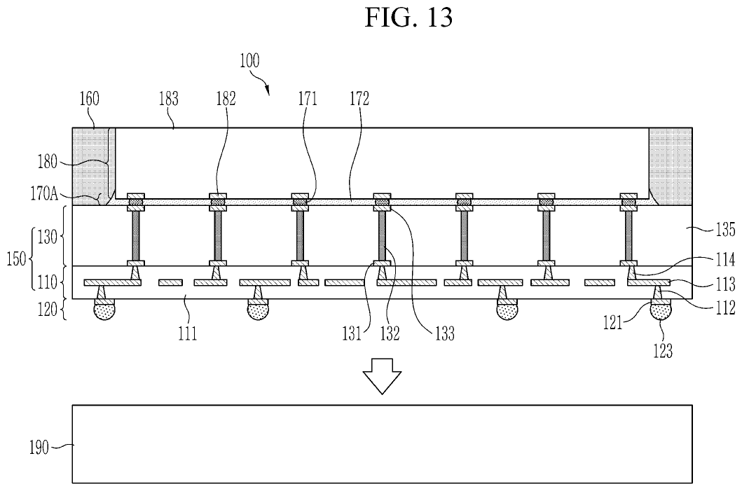

FIG. 13 is a cross-sectional view showing de-bonding the carrier 190 from the external connection structure 120.

Referring to FIG. 13, the carrier 190 can be removed from the external connection structure 120, while external connection members 123 and conductive pads 121 of the external connection structure 120 remain affixed to the redistribution layer structure 110.

FIG. 14 is a cross-sectional view showing a semiconductor package 200 in which a first three-dimensional integrated circuit (3D IC) structure 100 and a second three-dimensional integrated circuit (3D IC) structure 100A are mounted on a substrate, according to an embodiment of the disclosure.

Referring to FIG. 14, the semiconductor package 200 may include a substrate 210, the first three-dimensional integrated circuit (3D IC) structure 100 including the first semiconductor die 130 and the second semiconductor die 180, the second three-dimensional integrated circuit (3D IC) structure 100A including a third semiconductor die 130A and a fourth semiconductor die 180A, a first insulation member 261, and a second insulation member 262. The first three-dimensional integrated circuit (3D IC) structure 100 and the second three-dimensional integrated circuit (3D IC) structure 100A may be mounted on the substrate 210.

In various embodiments, the first semiconductor die 130 may include a system-on-chip (SOC), and the third semiconductor die 130A may include a memory structure (DRAM or high bandwidth memory (HBM)). In various embodiments, the first semiconductor die 130 may include a memory structure (DRAM or high bandwidth memory (HBM)), and the third semiconductor die 130A may include a system-on-chip (SOC). In various embodiments, the description of the first semiconductor die 130, the second semiconductor die 180, and the first three-dimensional integrated circuit (3D IC) structure 100, as described and illustrated in FIG. 1 and FIG. 2, may be applied to each of the third semiconductor die 130A, the fourth semiconductor die 180A and the second three-dimensional integrated circuit (3D IC) structure 100A.

The substrate 210 may include a first insulation layer 211, external connection members 212, connection pads 213, first wiring layers 214, second insulation layer 215, first vias 216, second wiring layers 217, second vias 218, third wiring layers 219, a third insulation layer 221 and connection members 222. In an embodiment, the substrate 210 may include an Ajinomoto build-up film (ABF) substrate. In an embodiment, the substrate 210 may include a printed circuit board. In an embodiment, the substrate 210 may include an embedded trace substrate (ETS) having a coreless form in which a core layer is removed. In another embodiment, substrates including fewer or greater numbers of insulating layers, wiring layers, vias, external connection members, and connection pads are within the scope of the present disclosure.

In various embodiments, the substrate 210 may include an electrical routing to relay a signal from the second semiconductor die 180 of the first three-dimensional integrated circuit (3D IC) structure 100 and a signal from the fourth semiconductor die 180A of the second three-dimensional integrated circuit (3D IC) structure 100A. A signal may be routed from second semiconductor die 180 to the fourth semiconductor die 180A, and from the fourth semiconductor die 180A to the second semiconductor die 180. The substrate 210 may include an electrical routing configured to relay an electrical signal from the second semiconductor die 180 and an electrical signal from the fourth semiconductor die 180A, where the electrical routing can include the through-silicon vias (TSV) 132. Because signals between the second semiconductor die 180 and the fourth semiconductor die 180A having I/Os of a fine pitch may be relayed to the substrate 210 without using a silicon bridge, the problem that the silicon bridge may be moved or incorrectly attached during the manufacturing process may be avoided. Also, the problem of warpage of the semiconductor package due to the silicon bridges may be avoided, and thus, yield of the semiconductor package may be enhanced.

In addition, in contrast to using a silicon bridge, where the structure of the semiconductor package can be complicated to adjust for the overlay error of the silicon bridges due to movement or incorrect attachment during a manufacturing process, the silicon bridge is not used, and accordingly, the semiconductor package may be formed in a simpler structure.

In various embodiments, the connection pad 213, the first wiring layer 214, the second insulation layer 215, the first via 216, the second wiring layer 217, the second via 218, the third wiring layer 219 and the connection member 222 may include at least one of copper, nickel, zinc, gold, silver, platinum, palladium, chromium, titanium, or an alloy thereof. In an embodiment, the first insulation layer 211 may include a solder resist. In an embodiment, the second insulating layer 215 may include at least one of a thermosetting epoxy resin, a thermoplastic epoxy resin, and a resin containing a filler. In an embodiment, the third insulation layer 221 may include solder resist. In an embodiment, the external connection member 212 may include at least one of tin, silver, lead, nickel, copper, or an alloy thereof.

In various embodiments, the first insulation member 261 may be disposed on the bottom surface and a portion of the side surface of the first three-dimensional integrated circuit (3D IC) structure 100, and may surround the external connection members 123 of the first three-dimensional integrated circuit (3D IC) structure 100. The second insulation member 262 may be disposed on the bottom surface and a portion of the side surface of the second three-dimensional integrated circuit (3D IC) structure 100A, and may surround an external connection members 123A of the second three-dimensional integrated circuit (3D IC) structure 100A (which corresponds to the external connection members 123 of the first three-dimensional integrated circuit (3D IC) structure 100). The first insulation member 261 may be between the first semiconductor die 130 and the third insulation layer 221 of the substrate 210. The second insulation member 262 may be between the third semiconductor die 130A and the third insulation layer 221 of the substrate 210.

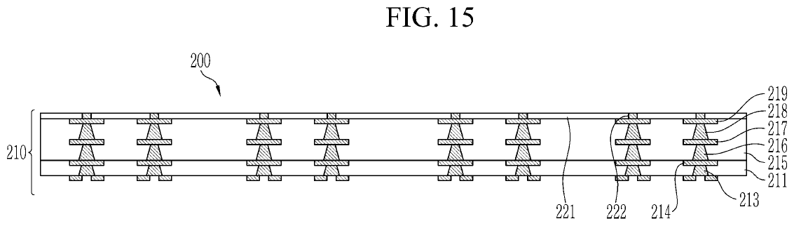

FIG. 15 is a cross-sectional view showing a substrate 210, according to an embodiment of the disclosure.

Referring to FIG. 15, the substrate 210 can be a multilayer structure that can provide electrical connections through the structure. Before the first three-dimensional integrated circuit (3D IC) structure 100 and the second three-dimensional integrated circuit (3D IC) structure 100A are mounted on the substrate 210, the substrate 210 can undergo a pretreatment process utilizing UV ultraviolet rays, plasma, or baking. The pretreatment process can clean and prepare the third insulation layer 221 and connection members 222 for mounting and electrical connection of the first three-dimensional integrated circuit (3D IC) structure 100 and the second three-dimensional integrated circuit (3D IC) structure 100A.

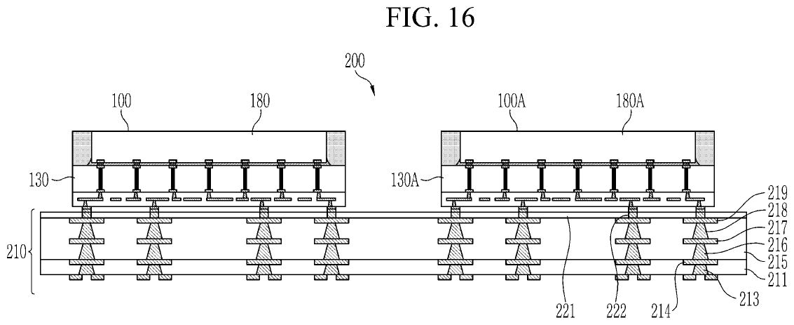

FIG. 16 is a cross-sectional view showing mounting of the first three-dimensional integrated circuit (3D IC) structure 100 and the second three-dimensional integrated circuit (3D IC) structure 100A on the substrate 210. Each of the first three-dimensional integrated circuit (3D IC) structure 100 and the second three-dimensional integrated circuit (3D IC) structure 100A can be attached to the substrate 210 and electrically connected to connection members 222.

Referring to FIG. 16, the first three-dimensional integrated circuit (3D IC) structure 100 and the second three-dimensional integrated circuit (3D IC) structure 100A may be mounted on the substrate 210 by a flip-chip bonding.

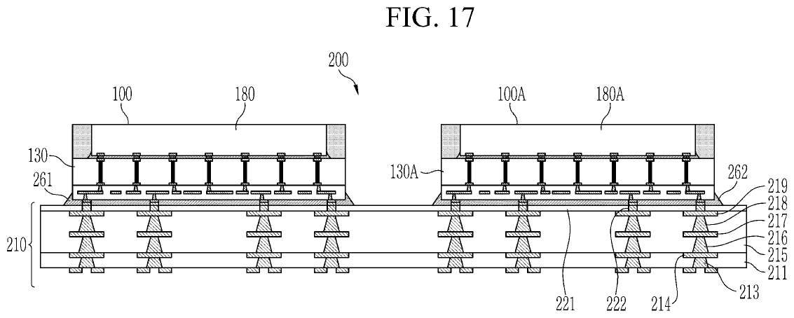

FIG. 17 is a cross-sectional view showing forming the first insulation member 261 between the substrate 210 and the first three-dimensional integrated circuit (3D IC) structure 100 and forming the second insulation member 262 between the substrate 210 and the second three-dimensional integrated circuit (3D IC) structure 100A to form the semiconductor package 200.

Referring to FIG. 17, the first insulation member 261 may be applied to the bottom surface and a portion of the side surface of the first three-dimensional integrated circuit (3D IC) structure 100, and the second insulation member 262 may be applied to the bottom surface and a portion of the side surface of the second three-dimensional integrated circuit (3D IC) structure 100A. In an embodiment, the first insulation member 261 and the second insulation member 262 may each include a molded under-fill (MUF). In an embodiment, the first three-dimensional integrated circuit (3D IC) structure 100 and the second three-dimensional integrated circuit (3D IC) structure 100A may be molded on the substrate 210 by a molding material.

Thereafter, the external connection members 212 is formed on a bottom surface of the substrate 210.

While the embodiments of this invention have been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package, comprising:
a first three-dimensional integrated circuit structure on a substrate; and
a second three-dimensional integrated circuit structure on the substrate,
wherein the first three-dimensional integrated circuit structure comprises:
a first interposer comprising a first semiconductor die; and
a second semiconductor die on the first interposer,
wherein the second three-dimensional integrated circuit structure comprises:
a second interposer comprising a third semiconductor die; and
a fourth semiconductor die on the second interposer,
wherein the substrate comprises an electrical routing configured to relay a signal from the second semiconductor die and a signal from the fourth semiconductor die.

2. The semiconductor package of claim 1, wherein:
the first interposer electrically connects the substrate with the second semiconductor die;
the first semiconductor die is free of active and passive devices;
the second interposer electrically connects the substrate with the fourth semiconductor die; and
the third semiconductor die is free of active and passive devices.

3. The semiconductor package of claim 1, wherein the substrate comprises an Ajinomoto build-up film (ABF) substrate.

4. The semiconductor package of claim 1, wherein the first semiconductor die and the third semiconductor die comprise a silicon interposer, respectively.

5. The semiconductor package of claim 4, wherein the silicon interposer comprises a plurality of through-silicon vias (TSV).

6. The semiconductor package of claim 1, wherein the first interposer and the second interposer further comprise a redistribution layer structure, respectively.

7. The semiconductor package of claim 1, wherein the second semiconductor die comprises system-on-chip (SOC).

8. The semiconductor package of claim 1, wherein the fourth semiconductor die comprises a high bandwidth memory (HBM).

9. The semiconductor package of claim 1, wherein:
the first three-dimensional integrated circuit structure further comprises a first molding material that molds the second semiconductor die on the first semiconductor die; and
the second three-dimensional integrated circuit structure further comprises a second molding material that molds the fourth semiconductor die on the third semiconductor die.

10. A semiconductor package, comprising:
a plurality of first connection members electrically connecting a first three-dimensional integrated circuit structure to a substrate;
and
a plurality of second connection members electrically connecting a second three-dimensional integrated circuit structure to the substrate
wherein the first three-dimensional integrated circuit structure comprises:
a first interposer comprising a first semiconductor die;
a second semiconductor die on the first interposer; and
a plurality of third connection members electrically connecting the second semiconductor die to the first interposer
wherein the second three-dimensional integrated circuit structure comprises:
a second interposer comprising a third semiconductor die;
a fourth semiconductor die on the second interposer; and
a plurality of fourth connection members electrically connecting the fourth semiconductor die to the second interposer, and
wherein the substrate comprises an electrical routing configured to relay a signal from the second semiconductor die and a signal from the fourth semiconductor die.

11. The semiconductor package of claim 10, wherein:
a pitch of neighboring first connection members among the plurality of first connection members is larger than a pitch of neighboring third connection members among the plurality of third connection members; and
a pitch of neighboring second connection members among the plurality of second connection members is larger than a pitch of neighboring fourth connection members among the plurality of fourth connection members.

12. The semiconductor package of claim 10, wherein the plurality of first connection members and the plurality of second connection members comprises solder balls or conductive bumps.

13. The semiconductor package of claim 10, wherein the plurality of third connection members and the plurality of fourth connection members comprises micro-bumps.

14. The semiconductor package of claim 10, further comprising:
a first insulation member disposed between the substrate and the first three-dimensional integrated circuit structure, and configured to surround the plurality of first connection members; and
a second insulation member disposed between the substrate and the second three-dimensional integrated circuit structure, and configured to surround the plurality of second connection members.

15. The semiconductor package of claim 14, wherein the first insulation member and the second insulation member comprise a molded under-fill (MUF).

16. The semiconductor package of claim 10, wherein:
the first three-dimensional integrated circuit structure further comprises a third insulation member, wherein the third insulation member is disposed between the first interposer and the second semiconductor die and surrounds the plurality of third connection members; and
the second three-dimensional integrated circuit structure further comprises a fourth insulation member, wherein the fourth insulation member is disposed between the second interposer and the fourth semiconductor die and surrounds the plurality of fourth connection members.

17. The semiconductor package of claim 16, wherein the third insulation member and the fourth insulation member comprise a nonconductive film (NCF).

18. A method for manufacturing a semiconductor package, the method comprising:
forming a through-silicon via in each of a first wafer and a second wafer;
forming a first redistribution layer structure on the first wafer to form a first interposer, and forming a second redistribution layer structure on the second wafer to form a second interposer;
mounting a first semiconductor die on the first interposer to form a first three-dimensional integrated circuit structure, and mounting a second semiconductor die on the second interposer to form a second three-dimensional integrated circuit structure; and
mounting the first three-dimensional integrated circuit structure and the second three-dimensional integrated circuit structure on a substrate
wherein the substrate comprises an electrical routing configured to relay a first signal from the first semiconductor die and a second signal from the second semiconductor die.

19. The semiconductor package of claim 18, further comprising pretreating the substrate, prior to the mounting the first three-dimensional integrated circuit structure and the second three-dimensional integrated circuit structure on the substrate.

20. The semiconductor package of claim 18, further comprising filling an under-fill material between the substrate and the first three-dimensional integrated circuit structure, and between the substrate and the second three-dimensional integrated circuit structure.
